(19) United States
(12) Patent Application Publication
(10) Pub. No.: US 2007/0222052 A1
(43) Pub. Date: Sep. 27, 2007

(54) WIRING STRUCTURE, MULTILAYER WIRING BOARD, AND ELECTRONIC DEVICE

(75) Inventor: Masanao Kabumoto, Kagoshima (JP)

Correspondence Address: DITTHAVONG MORI & STEINER, P.C., 918 Prince St., Alexandria, VA, 22314, US

(73) Assignee: KYOCERA Corporation, Kyoto (JP)

(21) Appl. No.: 11/690,482

(22) Filed: Mar. 23, 2007

(30) Foreign Application Priority Data
Mar. 24, 2006 (JP) 2006-83154

(51) Int. Cl. H01L 23/02

(52) U.S. Cl. 257/679

(57) ABSTRACT

A wiring structure includes a general signal line, a differential signal line having a pair of signal wiring lines and a reference potential layer. The signal wiring lines respectively transmit differential signals of which waveforms are inverted from each other. The reference potential layer is arranged to have a distance from the general signal line and the differential signal line, and has a non-formed portion in a region to be electromagnetically coupled to the differential signal line.

### CROSS-REFERENCE TO RELATED APPLICATIONS

The present application claims priority under 35 U.S.C. §119 to Japanese Patent Application No. 2006-83154, filed Mar. 24, 2006, entitled “WIRING STRUCTURE, MULTILAYER WIRING BOARD, AND ELECTRONIC DEVICE.” The contents of this application are incorporated herein by reference in their entirety.

### BACKGROUND OF THE INVENTION

1. Field of the Invention

The present invention relates to an wiring structure having a differential signal line suitable for connecting such electronic elements as rapidly-operating semiconductor elements, optical semiconductor elements, etc, a multilayer wiring board, and an electronic device using the same, and more particularly, to an wiring structure having a differential signal line and a general signal line, a multilayer wiring board, and an electronic device.

2. Description of the Related Art

Conventionally, such electronic elements as representative semiconductor elements, e.g. for a microprocessor or an ASIC (Application Specific Integrated Circuit), etc are built in a multilayer wiring board so as to be used as electronic devices. With a growing demand for improved information processing capability, operating speed of the semiconductor elements is becoming higher. Thus, for signal wiring lines of internal wiring lines in the multilayer wiring board, improved electric characteristic has been demanded such as characteristic impedance matching or crosstalk noise reduction among the signal wiring lines.

In response to the demand, a strip line structure or a micro-strip line structure is used as a line structure of signal arrangement. In the micro-strip line structure, a wide ground conductive layer is formed above or below the signal wiring lines through an insulation layer. In the strip line structure, a wide ground conductive layer is formed above and below the signal wiring lines through the insulation layer.

Recently, the semiconductor elements operate at a further higher speed and thus can transmit a high frequency signal of about several GHz. Two methods are used in the transmission of the high frequency signal, that is, a non-equilibrium transmission path method and an equilibrium transmission path method. In the non-equilibrium transmission path method, the high frequency signal is transmitted to a ground conductive layer and a signal wiring line (general signal line). In the equilibrium transmission path method, the high frequency signal is transmitted to a ground conductive layer and two signal wiring lines (differential signal lines) substantially parallel to each other. Regarding the differential signal lines, 2-phase signals of an inversion signal and a non-inversion signal are respectively input to the signal wiring lines, and then difference thereof is regarded as one signal. As a result, there is an advantage in noise offset, signal transmission with less distortion, and faster operation. Detailed examples thereof are disclosed in Japanese Unexamined Patent Application Publication No. 2-240994.

In particular, in a multilayer wiring board equipped with a semiconductor device such as ASIC, many pins are required to achieve high performance. In order to avoid a package from being enlarged in size due to many pins, a differential signal line is used when transmitting a signal that is significantly affected by noise or the like, and a conventional general signal line is used for other signals. Thus, the differential signal line and the general signal line are used together in one multilayer wiring board. In such a multilayer wiring board, characteristic impedance matching needs to be carried out according to each transmission method. In general, the general signal line is matched to 50Ω, and the differential signal line is matched to 100Ω.

The characteristic impedance matching of a signal wiring line is generally carried out by using (1) a method of adjusting the width of a signal wiring line or (2) a method of adjusting the thickness or permittivity of an insulation layer between a signal wiring line and a ground conductive layer.

When the characteristic impedance matching is carried out by using the method of adjusting the width of a signal wiring line, the wiring width of the differential signal line has to be greater than that of the general signal line. Therefore, wiring density cannot increase. On the other hand, when the characteristic impedance matching is carried out by using the method of adjusting the thickness or permittivity, the thickness of one insulation layer can be changed generally. In practice, however, the thickness of the insulation layer needs to be partially changed, or the material of the insulation layer needs to be partially changed, which is not practical and thus not easy to be implemented.

In order to solve the problems, a multilayer wiring board 16 shown in a cross-section view of FIG. 5 is disclosed in Japanese Unexamined Patent Application Publication No. 2002-158452. A differential signal line 12 is arranged in a region where an equilibrium transmission path is formed between an uppermost power conductive layer 18 or an uppermost ground conductive layer 14 and a lowermost power conductive layer 18 or a lowermost power conductive layer 14. In addition, the power conductive layer 18 or the ground conductive layer 14 is arranged on the same surface as the differential signal line 12, and a general signal line 11 is arranged between the power conductive layer 18 or the ground conductive layer 14 and the respective uppermost and lowermost power conductive layers 18 or ground conductive layers 14. Accordingly, there is a region where a non-equilibrium transmission path is vertically laminated.

According to the arrangement of the general signal line 11, the differential signal line 12, and the power conductive layer 18 or the ground conductive layer 14 in one multilayer wiring board 16, there is an advantage in that each impedance matching can be achieved without having to partially change the thickness or material of one insulation layer 1.

However, since five or more layers of the insulation layer 13 are required to form one differential signal line 12, the multilayer wiring board 16 becomes thick. Therefore, the multilayer wiring board cannot be formed in a thin film, which is necessary for minimization.

Furthermore, if the insulation layer has many layers, and the multilayer wiring board becomes thick, power/ground plane inductance increases between an electrode formed on one surface of the multilayer wiring board to connect a semiconductor element and an electrode formed on the other surface of the multilayer wiring board to connect an external board. Therefore, a high-speed operation of the semiconductor element is obstructed.

### SUMMARY OF THE INVENTION

The present invention has originated in order to overcome the above problems in the related art. An object of the present invention is to provide a multilayer wiring board which facilitates characteristic impedance matching between an equilibrium transmission path and a non-equilibrium transmission path both of which are formed on the multilayer wiring board so as to obtain high wiring density and so as to be able to deal with high-speed operation of semiconductor elements.

According to an aspect of the present invention, capacitance between a differential signal line and a ground conductive layer decreases, thereby increasing a characteristic impedance of the differential signal line. As a result, each characteristic impedance of a general signal line and the differential signal line can be matched without adjusting a thickness of an insulation layer formed between the general signal line and the ground conductive layer so as to be widely different from a thickness of an insulation layer formed between the differential signal line and the ground conductive line, or without adjusting a wiring width of the differential signal line so as to be greater than a wiring width of the general signal line. Therefore, it becomes possible to increase wiring density.

In addition, since a total number of insulation layers can be reduced, the thickness of the multilayer wiring board can be restricted. As a result, semiconductor elements built in the multilayer wiring board can operate at a high speed.

In addition, by adopting a structure having a plurality of opening portions arranged on the ground conductive layer with a desired distance from one another, a path is formed between the opening portions so that current can flow within the ground conductive layer in a direction crossing the differential signal line. As a result, the opening portions do not cause the increase of power/ground plane inductance, and thus power/ground noise caused by the increased power/ground plane inductance is not increased. Therefore, semiconductor elements can operate at better high speed.

In addition, with the aforementioned structure, when a length in a longitudinal direction of the differential signal line of the opening portions is not more than ¼ of the wavelength of a signal transmitted to the differential signal line, the signal transmitted to the differential signal line can be prevented from being leaked out of the opening portions. As a result, the signal can be satisfactorily transmitted at a high speed.

### BRIEF DESCRIPTION OF THE DRAWINGS

The above and other features and advantages of the present invention will become more apparent by describing in detail exemplary embodiments thereof with reference to the attached drawings in which:

FIG. 1A is a cross-sectional view of an example of a multilayer wiring board according to an embodiment of the present invention, and FIG. 1B is an enlarged view of a substantial part of FIG. 1A, viewed from the top;

FIG. 2 is a cross-sectional view of an example of a multilayer wiring board according to another embodiment of the present invention;

FIG. 3 is an enlarged view of a substantial part of an example of a multilayer wiring board, viewed from the top, according to an embodiment of the present invention;

FIG. 4 is an enlarged view of a substantial part of an example of a multilayer wiring board, viewed from the top, according to another embodiment of the present invention; and

FIG. 5 is a cross-sectional view of an example of a conventional multilayer wiring board.

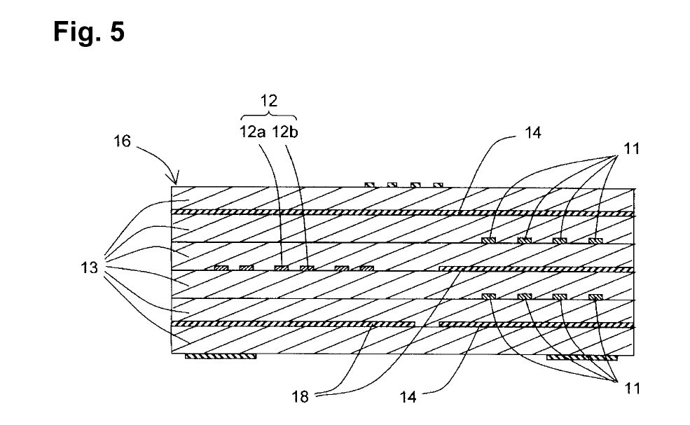

### DETAILED DESCRIPTION OF THE INVENTION

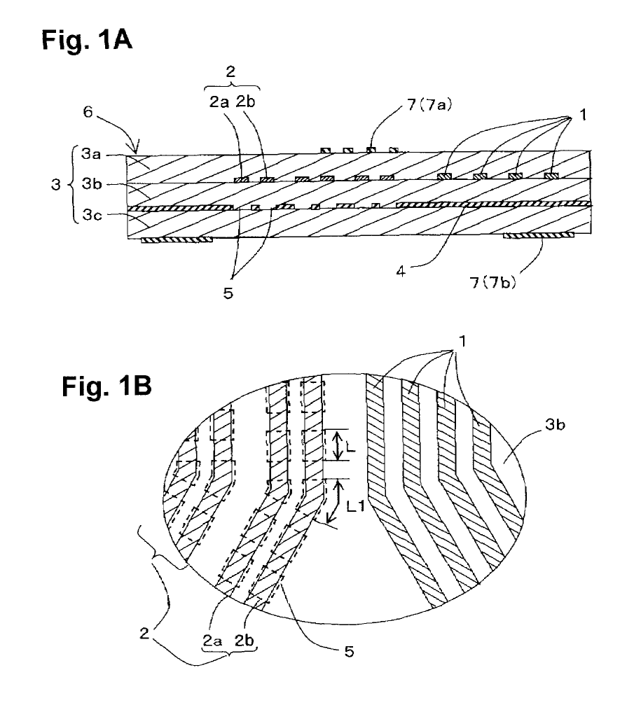

Hereinafter, a multilayer wiring board of the present invention will be described in detail. FIG. 1 is a view illustrating a multilayer wiring board according to an embodiment of the present invention, in which FIG. 1A is a cross-sectional view of the multilayer wiring board of the present invention, and FIG. 1B is an enlarged view of a substantial part of FIG. 1A, viewed from the top. Referring to the figures, provided are a general signal line 1, a differential signal line 2, a first signal line path 2a constituting the differential signal line 2, a second signal line path 2b constituting the differential signal line 2, an insulation layer 3, a ground conductive layer 4 acting as a reference potential layer, a non-formed portion (hereinafter, referred to as an opening portion) 5 in the ground conductive layer 4, a multilayer wiring board 6, and a surface wiring line 7.

In the present invention, the reference potential layer includes a so-called ground conductive layer and a power conductive layer. Further, the reference potential layer is a conductive layer determined to have a reference voltage. In addition, the general signal line is constructed so that a single signal wiring line is arranged with a certain distance with respect to the reference potential layer. The general signal line constitutes a non-equilibrium transmission path through which a high frequency signal is transmitted. Meanwhile, the differential signal line is constructed with a pair of signal wiring lines juxtaposed with a certain distance therebetween and substantially parallel to each other. Each signal wiring line is spaced apart from the reference potential layer by the almost same distance. A non-inversion signal is input to one of the signal wiring line of the differential signal line, and an inversion signal is input to the other signal wiring line, thereby forming an equilibrium transmission path through which a high frequency signal is transmitted. A difference of 2-phase signals of the input inversion signal and non-inversion signal is regarded as one signal. Therefore, noise can be offset, and signal transmission can be achieved with less distortion, thereby achieving better speeding up.

Moreover, in the present invention, for example, the general line signal may transmit a signal having a frequency of not more than 1 GHz, and the differential signal line may transmit a high frequency signal of 2 GHz and above.

The multilayer wiring board 6 includes the ground conductive layer 4 arranged, when viewed from the top, through the insulation layer 3 so as to overlap the general signal line 1 and the differential signal line 2 which are arranged on the same surface between layers of the insulation layer 3 constituting a multilayer board. The ground conductive layer 4 includes the opening portion 5 formed at a region overlapping the differential signal line 2 when viewed from the top.

According to the embodiment shown in FIG. 1, as shown in FIG. 1A, an upper surface of the insulation layer 3b is provided with the general signal line 1 and the differential signal line 2 which is constructed with the two signal lines 2a and 2b substantially parallel to each other. Through the lower insulation layer 3b, the ground conductive layer 4 is formed to have a wide region that faces the general signal line 1 and the differential signal line 2. As shown in FIG. 1B, the ground conductive layer 4 is provided with the opening portion 5 (indicated by dashed lines) formed at a region overlapping the differential signal line 2 when viewed from the top. Each signal wiring line of the general signal line 1 and the differential signal line 2 forms a micro-strip structure along with the ground conductive layer 4. The surface wiring line 7 is formed on the surface of the multilayer wiring board 6. An electrode pad 7a is formed on the upper surface of the multilayer wiring board 6 so as to connect such electronic elements as semiconductor elements, etc, and a terminal electrode 7b is formed on the lower surface to connect the multilayer wiring board 6 to an external wiring board (not shown). The surface wiring line 7, the electrode pad 7a, the terminal electrode 7b, the general signal line 1, the differential signal line 2, and the ground conductive layer 4 are properly and electromagnetically coupled by a through-conductor (not shown) passing through the insulation layer 3.

According to the multilayer wiring board 6 having this structure of the present invention, the ground conductive layer 4 facing the differential signal line 2 occupies a small area, and thus a capacitance between the differential signal line 2 and the ground conductive layer 4 decreases, thereby increasing a characteristic impedance of the differential signal line 2. Therefore, the insulation layer 3 (insulation layer 3b) arranged between the general signal line 1 and the ground conductive layer 4 and between the differential signal line 2 and the ground conductive layer 4 may have the same thickness so that each characteristic impedance of the general signal line 1 and the differential signal line 2 can be matched without having to increase a wiring width of the general signal line 1 so as to be greater than that of the differential signal line 2.

In addition, since the wiring width of the general signal line 1 does not have to be greater than that of the differential signal line 2, any wiring lines can have the same small width. Thus, high wiring density can be achieved.

And also, characteristic impedances of the general signal line 1 and the differential signal line 2 may be matched under the condition where the general signal line 1 and the differential signal line 2 are formed on the same layer and where the thickness of the insulation layer 3 (insulation layer 3b) between the general signal line 1 and the ground conductive layer 4 has the same thickness as that between the differential signal line 2 and the ground conductive layer 4. As in the conventional case, each of the general signal line 1 and the differential signal line 2 do not have to be formed on a different insulation layer 3 in a perpendicular direction, respectively. Instead, a simple structure having only two insulation layers may be adopted in which each of the layers is formed above and below the general signal line 1 and the differential signal line 2. Even when both the non-equilibrium transmission path and the equilibrium transmission path are formed on the multilayer wiring board 6, there is no need for increasing the thickness of the multilayer wiring board. Accordingly, power/ground plane inductance is not increased, and thus power/ground noise caused by the increased power/ground plane inductance is not occurred. Therefore, high-speed operation of semiconductor elements built in the multilayer wiring board 6 is possible.

Generally, in many cases, the characteristic impendence of the general signal line 1 is set to 50Ω, and the characteristic impedance of the differential signal line 2 is set to 100Ω. The width of the opening portion 5 is designed depending on the relative permittivity of the insulation layer 3b, the thickness of the insulation layer 3b, the width of the general signal line 1 or the differential signal line 2, and the distance between the signal line path 2a and the signal line path 2b of the differential signal line 2. Thus, each of characteristic impedance can be easily set to the above desired value.

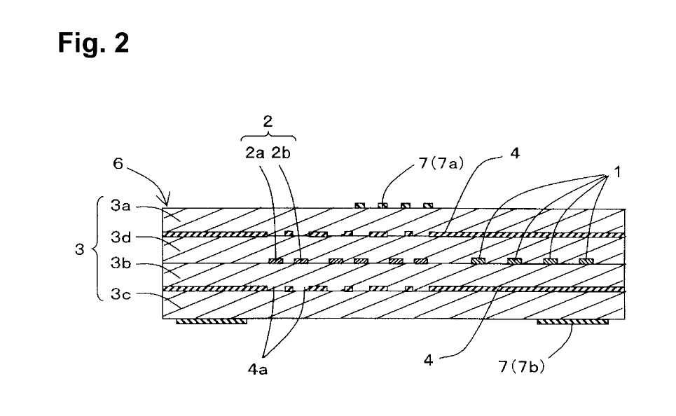

Referring to FIG. 2, similarly to the cross-sectional view of FIG. 1A, a strip line structure may also be adopted in which a ground conductive layer 4 is formed on a general signal line 1 and a differential signal line 2 through an insulation layer 3b. In this case, similarly to the upper ground conductive layer 4, an opening portion 5 is formed in a region overlapping the differential signal line 2 when viewed from the top. Either the upper ground conductive layer 4 or the lower ground conductive layer 4 may be a power conductive layer. Although the ground conductive layer 4 is arranged below the general signal line 1 and the differential signal line 2 in the embodiment of FIG. 1, the ground conductive layer 4 may be arranged above thereof.

Regarding the opening portion 5, preferably, a plurality of opening portions 5 are arranged in a longitudinal direction of the differential signal line 2 with a distance. With this structure, a path is formed between the opening portions 5 so that current flows within the ground conductive layer 4 in a direction crossing the differential signal line 2. Accordingly, the opening portions 5 do not cause the increase of power/ground plane inductance, and thus power/ground noise caused by the increased power/ground plane inductance is not increased. Therefore, the built-up semiconductor elements can operate at a high speed.

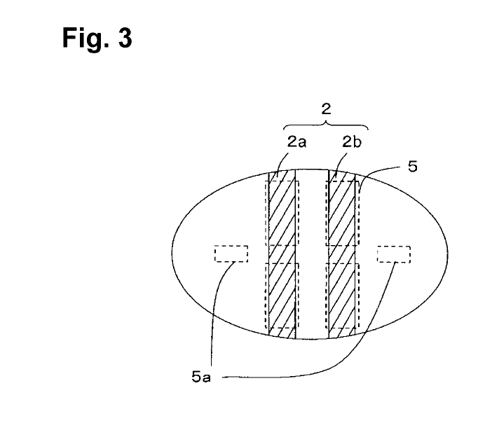

A gap formed between the opening portions 5 is preferably as small as possible. This is because the ground conductive layer 4 and the differential signal line 2 face each other in the gap between the opening portions 5, and thus a capacitance therebetween becomes greater than that of a region where the opening portions 5 are formed, thereby decreasing the impedance of the differential signal line 2 in this region. In addition, by decreasing the gap between the opening portions 5, the resistance of this region increases. This may result in the increase of power/ground plane inductance. In this case, as shown in FIG. 3, similarly to the enlarged view of a substantial part of FIG. 1B, a gap is formed to have a suitable resistance, and an opening portion 5a is formed near the gap so as to adjust impedance. As a result, it is possible to minimize the affect of decreased impedance of the differential signal line 2.

In addition, in each opening portion 5, the length (indicated by L in FIG. 1B) of the opening portion 5 in a longitudinal direction of the differential signal line 2 overlapping the opening operation is preferably not more than ¼ of the wavelength of a high frequency signal transmitted to the differential signal line 2. For this reason, a signal transmitted to the differential signal line 2 can be restricted from being leaked out of the opening portion 5. Therefore, the signal is transmitted with less loss, thereby improving transmission of high-speed signal.

As shown in FIG. 1B, if the differential signal line 2 has a bent portion, and the ground conductive layer 4 is provided with the opening portion 5 formed in a region overlapping the bent portion, then the length of the opening portion 5 in the longitudinal direction of the differential signal line 2 corresponds to an outer longer side of the bent portion (indicated by L1 in FIG. 1B.).

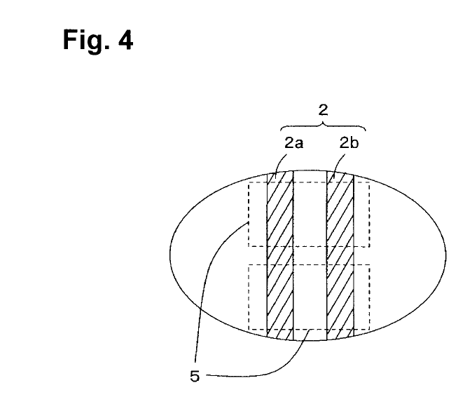

In this case, as shown in FIG. 1, the opening portion 5 is constructed so that a pair of opening portions 5 are formed to overlap a pair of signal lines 2a and 2b constituting the differential signal line 2. However, as shown in FIG. 4, similarly to the enlarged view of the substantial part of FIG. 1B, one opening portion 5 may be formed to overlap both the pair of signal lines 2a and 2b.

For example, assume that the relative permittivity of the insulation layer 3b between the differential signal line 2 and the ground conductive layer 4 is 5.4, and the thickness of the insulation layer is 58 μm. In this case, if the general signal line 1 has a line width of 50 μm and a thickness of 10 μm, then, the characteristic impedance of the general signal line 1 is matched to 50Ω. Further, if the pair of signal lines 2a and 2b constituting the differential signal line 2 each have a line width of 50 μm and a thickness of 10 μm, a gap between wiring lines is 150 μm, and each width of the pair of opening portions 5 respectively overlapping the signal lines 2a and 2b of the differential signal line 2 is 40 μm to 95 μm, then the characteristic impedance of the differential signal line 2 can be matched to about 100Ω. Here, the impedance of about 100Ω is in the range of ±5% which is generally required for impedance matching, that is, 95˜105Ω. Regarding the width, each of the pair of opening portion 5 is arranged so that a center line passing through a widthwise center of the opening portion 5 is disposed to overlap a center line of each of the pair of signal lines 2a and 2b when viewed from the top. In this case, without the opening portion 5 formed on the ground conductive layer 4, the characteristic impedance of the differential signal line 2 becomes 93Ω.

In this example, the pair of signal lines 2a and 2b constituting the differential signal line 2 each have the same line width of 50 μm. In this case, if the only gap between wiring lines is 100μm, each width of the pair of opening portions 5 is 80 μm to 160 μm, the characteristic impedance of the differential signal line 2 can be matched to about 100Ω. Herein, if the width of the opening portion 5 is 150 μm and above, one opening portion 5 is formed to overlap both sides of the pair of signal lines 2a and 2b shown in FIG. 4, whereas if it exceeds 150 μm, the pair of opening portions 5 overlap each other. For example, if the width is 160 μm, the pair of opening portions 5 overlap each other by 10 μm, thereby forming one opening portion 5 having a width of 310 μm.

Furthermore, from the preceding example, if the insulation layer 3b has a thickness of 50 μm, and the general signal line 1 has a line width of 40 μm, then the characteristic impedance of the general signal line 1 is matched to 50Ω. Meanwhile, if the pair of signal lines 2a and 2b constituting the differential signal line 2 each have the same line width of 40 μm, and each gap between wiring lines is 150 μm, the characteristic impedance of the differential signal line 2 can be matched to about 100Ω by adjusting the width of the opening portion 5 to 15 μm to 75 μm.

In addition, from the preceding example, if the general signal line 1 and the differential signal line 2 have the same line width or the same gap between wiring lines and if the insulation layer 3b has a relative permittivity of 7.6, the characteristic impedance of the general signal line 1 is matched to 50Ω by adjusting the thickness of the insulation layer 3b to 80 μm. Further, the characteristic impedance of the differential signal line 2 can be about 100Ω by adjusting the width of the opening portion 5 to 115 μm to 260 μm.

Accordingly, the width of the opening portion 5 is properly designed according to the relative permittivity and thickness of the insulation layer 3b and the line widths or wiring gaps of the signal lines 2a and 2b of the differential signal line 2.

Although irrelevant to a characteristic impedance value, as described above, in order to restrict a signal transmitted to the differential signal line 2 from being leaked out of the opening portion 5, the length in the longitudinal direction of the differential signal line 2 of the opening portion 5 is preferably not more than ¼ of the wavelength of a high frequency signal transmitted to the differential signal line 2. For example, if the frequency of a signal transmitted to the differential signal line 2 is 10 GHz, the length of the opening portion 5 is adjusted to be not more than 3.2 mm.

As described above, it is preferable that the gap between the opening portions 5 is as small as possible. However, if the gap is about 0.3 mm, it has less impact on partial degradation of impedance in the longitudinal direction of the differential signal line 2, and also power/ground plane inductance is less affected. Moreover, the size of the opening portion 5a for adjusting impedance, similarly to the opening portion 5, is properly designed according to the relative permittivity and thickness of the insulation layer 3b and the line widths or wiring gaps of the signal lines 2a and 2b of the differential signal line 2. The length of the opening portion 5a in the longitudinal direction of the differential signal line 2 is preferably the same as the gap between the opening portions 5 since the characteristic impedance matching can be further accurately achieved over the entire area in the longitudinal direction of the differential signal line 2.

The multilayer wiring board 6 of the present invention is used as a package for containing such electronic element as a package for containing semiconductor elements, etc, a board for mounting electronic elements, a so-called multi-chip module or multi-chip package equipped with a plurality of semiconductor elements, a mother board, and so on. Further, a coil inductor, a cross inductor, a chip condenser, or an electrolyte condenser may be mounted on the multilayer wiring board 6, thereby constituting an electronic circuit module. Furthermore, such electronic elements as semiconductor elements, etc are built in the multilayer wiring board 6 of the present invention, and then the electronic element, the general signal line 1, and the differential signal line 2 are electromagnetically coupled, thereby achieving an electronic device of the present invention.

The insulation layer 3 of the multilayer wiring board 6 is made of such a ceramic material as an aluminum oxide sintered body, an aluminum nitride sintered body, a silicon carbide sintered body, a silicon nitride sintered body, a mullite sintered body, glass ceramics, etc or such an organic insulation material as polyimide, epoxy resin, fluoride resin, poly-norbornene, or benzo-cyclo-butene, etc. When made of the organic insulating material, a complex insulation material may be used in which inorganic insulation material powder of ceramic powder contained in resin is dispersed or an organic insulation material is impregnated into glass fiber.

If the insulation layer 3 is made of the ceramic material, for example, the conventionally known ceramic green sheet lamination method may be used in a manufacturing process as described below. That is, an organic binder or solvent is added with suitable ingredient powder of the ceramic material, and optionally, with a dispersing agent or a plasticizer, and a slurry produced using such a mixing method as a boll mill method, etc is formed in a sheet-shape by using such a molding method as a doctor blade method, thereby obtaining a ceramic green sheet.

The obtained ceramic green sheet is laminated above and below the insulation layer 3, the resultant laminated body is then heated at a temperature of 100 to 800° C. to be debound and thereafter is sintered at a temperature of 800 to 1600° C. When the insulation layer 3 is made of aluminum oxide sintered body, sintering is performed at a temperature of 1600° C. in a reductive atmosphere. On the other hand, when made of the glass ceramics, sintering is performed at a temperature of 800 to 1100° C. in a nitride atmosphere or in the air according to a wiring conductor to be used. In the case of the reductive atmosphere or the nitride atmosphere, debounding is enhanced by humidifying.

In this case, the general signal line 1, the differential signal line 2, the ground conductive layer 4, and the surface wiring line 7 are made of such a metal powder metallizer having a high melting point as tungsten (W), molybdenum (Mo), molybdenum manganese (Mo—Mn), etc when the insulation layer 3 is made of the aluminum oxide sintered body. On the other hand, the general signal line 1, the differential signal line 2, the ground conductive layer 4, and the surface wiring line 7 are made of such a metal powder metallizer having a low melting point as copper (Cu), silver (Ag), and silver-palladium (Ag—Pd), etc when the insulation layer 3 is made of the glass ceramics. The metal powder is added and mixed with a suitable organic binder or solvent, and optionally, a dispersing agent, etc., and then the resultant is kneaded by such a kneading element as a boll mill, three roll mill, a planetary mixer, and so on. Metal paste is imprint-coated with a desired pattern on the ceramic green sheet, and this is sintered along with a laminating body of the ceramic green sheet, thereby forming the multilayer wiring board.

If the insulation layer 3 is made of the ceramic material, in order to transmit a high frequency signal, it is preferable to use glass ceramics having a relatively low relative permittivity, a copper material having a low resistance, or a silver metallizer.

On the other hand, if the insulation layer 3 is made of an organic insulation material, e.g., such a thermosetting resin as epoxy resin, etc., then the manufacturing process is carried out by alternately laminating the insulation layer 3 and a thin film wiring conductive layer, wherein the insulation layer 3 is made of organic resin such as epoxy resin which is formed when an organic resin precursor is formed using a spin coating method or a cotton coating method, and this is subject to a thermosetting process.

In this case, the general signal line 1, the differential signal line 2, the ground conductive layer 4, and the surface wiring line 7, each of which is composed of the thin film wiring conductive layer, are formed by using such a metal material as copper (Cu), silver (Ag), nickel (Ni), chromium (Cr), titanium (Ti), gold (Au), niobium (Nb), and their alloy. For example, a metal film may be formed using a sputtering method, a vacuum deposition method, or a plating method, and then a desired wiring pattern may be formed using a photolithographic method. Alternatively, the above elements may be formed such that the metal layer is formed by using a mask which is formed on the upper surface of the insulation layer 3 and has an opening portion having a desired wiring pattern shape, and thereafter the mask is removed.

The thickness of the insulation layer 3 is properly determined to satisfy such a condition as a mechanical rigidity or an electrical characteristic which meets a requirement according to a characteristic of a material of use.

The present invention should not be construed as being limited to the embodiments set forth herein; rather, various changes in form and details may be made therein without departing from the spirit and scope of the present invention. For example, besides the micro-strip line structure and the strip line structure shown in FIG. 2, the general signal line 1 and the differential signal line 2 may have a coplanar line structure in which a power wiring layer or a ground wiring layer is formed on the same surface of the insulation layer where the general signal line or the differential signal line is formed while a power wiring layer or a ground wiring layer being spaced apart (insulated) from the general signal line or the differential signal line and being sandwiched therebetween.

What is claimed is:

1. A wiring structure comprising:
a general signal line;
a differential signal line constructed with a pair of signal wiring lines respectively transmit differential signals of which waveforms are inverted from each other; and
a first reference potential layer arranged to have a distance from the general signal line and the differential signal line, and having a non-formed portion in a region to be electromagnetically coupled to the differential signal line.

2. The wiring structure according to claim 1, wherein the non-formed portion overlaps the differential signal line when viewed from a top of the first reference potential layer.

3. The wiring structure according to claim 1, wherein the general signal line and the differential signal line are formed on the same surface.

4. The wiring structure according to claim 1, wherein a plurality of the non-formed portions is arranged as a plural number to keep a distance therebetween.

5. The wiring structure according to claim 4, wherein the plurality each of the non-formed portions each has a length in an extended direction of the differential signal line and the length is not more than ¼ of the wavelength of a signal transmitted to the differential signal line.

6. The wiring structure according to claim 1, further comprising a second reference potential layer in an opposite side of the first reference potential layer with respect to the general signal line and the differential signal line.

7. A wiring structure comprising:
a general signal line;
a differential signal line constructed with a pair of signal wiring lines respectively transmit differential signals of which waveforms are inverted from each other; and
a first reference potential layer which is arranged to have a distance from the general signal line and the differential signal line,
wherein, when viewed from a top of the first reference potential layer, a ratio of an area of a region to be electromagnetically coupled to the differential signal line of the first reference potential layer to an area of the differential signal line is less than a ratio of an area of a region to be electromagnetically coupled to the general signal line of the first reference potential layer to an area of the general signal line.

8. The wiring structure according to claim 7, wherein the area of the region to be electromagnetically coupled to the differential signal line of the first reference potential layer is an overlap area of the first reference potential layer and the differential signal line, and the area of the region to be electromagnetically coupled to the general signal line of the first reference potential layer is an overlap area of the first reference potential layer and the general signal layer.

9. The wiring structure according to claim 7, wherein the general signal line and the differential signal line are formed on the same surface.

10. A multilayer wiring board comprising:
a general signal line;
a differential signal line constructed with a pair of signal wiring lines respectively transmit differential signals of which waveforms are inverted from each other; and
a first reference potential layer arranged above the general signal lines and the differential signal line through an insulation layer, and having a non-formed portion in a region to be electromagnetically coupled to the differential signal line.

11. The multilayer wiring board according to claim 10, wherein the non-formed portion overlaps the differential signal line when viewed from a top of the first reference potential layer.

12. The multilayer wiring board according to claim 10, wherein the general signal line and the differential signal line are formed on the same surface.

13. The multilayer wiring board according to claim 10, wherein a plurality of the non-formed portions is arranged as a plural number with a distance therebetween.

14. The multilayer wiring board according to claim 13, wherein the plurality each of the non-formed portions each has a length in an extended direction of the differential signal line and the length is not more than ¼ of the wavelength of a signal transmitted to the differential signal line.

15. The multilayer wiring board according to claim 10, further comprising a second reference potential layer in an opposite side of the first reference potential layer with respect to the general signal line and the differential signal line.

16. A multilayer wiring board comprising:
a general signal line;
a differential signal line constructed with a pair of signal wiring lines respectively transmit differential signals of which waveforms are inverted from each other; and
a first reference potential layer which is arranged to have a distance from the general signal line and the differential signal line,
wherein, when viewed from a top of the first reference potential layer, a ratio of an area of a region to be electromagnetically coupled to the differential signal line of the first reference potential layer to an area of the differential signal line is less than a ratio of an area of a region to be electromagnetically coupled to the general signal line of the first reference potential layer to an area of the general signal line.

17. The multilayer wiring board according to claim 16, wherein the area of the region to be electromagnetically coupled to the differential signal line of the first reference potential layer is an overlap area of the first reference potential layer and the differential signal line, and the area of the region to be electromagnetically coupled to the general signal line of the first reference potential layer is an overlap area of the first reference potential layer and the general signal layer.

18. The multilayer wiring board according to claim 16, wherein the general signal line and the differential signal line are formed on the same surface.

19. An electronic device comprising one or more electronic elements electromagnetically coupled to the multilayer wiring board, the general signal line, and the differential signal line of claim 10.

20. An electronic device comprising one or more electronic elements electromagnetically coupled to the multilayer wiring board, the general signal line, and the differential signal line of claim 16.
